(19) United States
(12) Patent Application Publication
(10) Pub. No.: US 2017/0370968 A1
(43) Pub. Date: Dec. 28, 2017

(54) CURRENT SENSOR

(71) Applicant: AISIN SEIKI KABUSHIKI KAISHA, Kariya-shi (JP)

(72) Inventors: Ken OKUMURA, Hekinan-shi (JP); Mamoru Tsuda, Nagoya-shi (JP)

(73) Assignee: AISIN SEIKI KABUSHIKI KAISHA, Kariya-shi (JP)

(21) Appl. No.: 15/622,097

(22) Filed: Jun. 14, 2017

(30) Foreign Application Priority Data
Jun. 27, 2016 (JP) 2016-126810

(51) Int. Cl. G01R 15/20; G01R 15/16; G01R 1/20; G01R 15/14; H01L 43/06; G01R 19/00

(52) U.S. Cl. CPC G01R 15/202; H01L 43/06; G01R 19/0092; G01R 1/20; G01R 15/142; G01R 15/16

(57) ABSTRACT

A current sensor includes: six or more bus bars; a core made of a magnetic material and having a base portion and seven or more arm portions which extend in a vertical direction from the base portion and are spaced apart from each other, and in which each of the bus bars is inserted into a gap formed between adjacent arm portions; and a main body configured to integrally hold the bus bars and the core in a state in which the bus bars and the core are insert-molded using polyphenylene sulfide (PPS) or polyphthalamide (PPA).

### CROSS REFERENCE TO RELATED APPLICATIONS

This application is based on and claims priority under 35 U.S.C. §119 to Japanese Patent Application 2016-126810, filed on Jun. 27, 2016, the entire contents of which are incorporated herein by reference.

### TECHNICAL FIELD

This disclosure relates to a current sensor which measures a current flowing in a conductor.

### BACKGROUND DISCUSSION

Recently, hybrid vehicles or electric vehicles have been distributed, which are provided with a three-phase alternating current motor (hereinafter, simply referred to as a “motor”) and an inverter. In these vehicles, the rotation of the motor is appropriately controlled by measuring a current flowing in the motor. Each of U-phase, V-phase, and W-phase terminals of the motor is connected to the inverter through a conductor (bus bar), and the magnitude of the current flowing in each bus bar is measured by a current sensor.

In a current sensor disclosed in JP 2014-006116 A (Reference 1), a plurality of cores and a plurality of bus bars, which are made of a magnetic material, are configured by insert molding using molding resin. In the current sensor, in a state in which the bus bars are inserted into an internal space of the cores. A magnetic flux, which is formed around the bus bars depending on the magnitude of the current flowing in the bus bars, is detected by a detecting device, and the magnitude of the current flowing in the bus bars is obtained by arithmetic calculation based on the magnitude of the detected magnetic flux.

The current sensor disclosed in Reference 1 is assembled by integrating six bus bars and six cores (magnetic cores), which are separated from one another and arranged in a staggered form, with a main body made of a resin by insert molding, and then mounting a Hall device (detecting device).

As described above, since the opposite ends of each bus bar are connected to the motor and the inverter, respectively, it is necessary to increase positional accuracy in respect to the end portions of the bus bar, which are supported by the main body of the current sensor. In the case in which the bus bars and the main body are integrated by insert molding, an interior of the mold is typically filled with a molten resin in a state in which the opposite ends of the bus bars are held in the mold. The bus bars are continuously held in the mold until the main body is formed and extracted from the mold, and as a result, the bus bars and the main body are integrated with each other. However, in some cases, after the resin molding, the end portions of the bus bars in the main body may deviate from a position where the bus bars are held in the mold.

In general, a contraction degree of a resin product during the curing of the resin product is smallest at a surface of the resin product and increases toward the interior of the resin product. When the resin is contracted in the inside of the main body, the bus bars receive a stress. Therefore, it is considered that a positional deviation of the end portions of the bus bars in the main body (current sensor) after the resin molding is caused by the stress.

Thus, a need exists for a current sensor which is not susceptible to the drawback mentioned above.

### SUMMARY

A feature of a current sensor according to an aspect of this disclosure resides in that the current sensor includes: six or more bus bars; a core made of a magnetic material and having a base portion and seven or more arm portions which extend in a vertical direction from the base portion and are spaced apart from each other, and in which each of the bus bars is inserted into a gap formed between adjacent arm portions; and a main body configured to integrally hold the bus bars and the core in a state in which the bus bars and the core are insert-molded using polyphenylene sulfide (PPS) or polyphthalamide (PPA).

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a perspective view of one side of a current sensor;

FIG. 2 is a perspective view of the other side of the current sensor;

FIG. 3 is a top plan view of a main part of the current sensor;

FIG. 4 is a partial perspective view illustrating a positional relationship between bus bars and a core;

FIG. 5 is a cross-sectional view of a main part of the internal structure of the current sensor;

FIG. 6 is a cross-sectional view of a main part of the internal structure of a current sensor of another exemplary embodiment; and

FIG. 7 is a cross-sectional view of a main part of the internal structure of a current sensor of another exemplary embodiment.

### DETAILED DESCRIPTION

Hereinafter, exemplary embodiments disclosed here will be described in detail.

### First Exemplary Embodiment

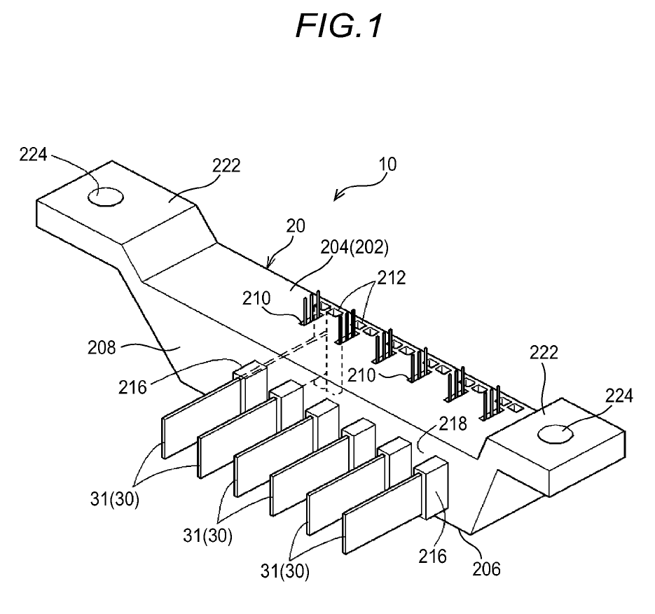

As illustrated in FIGS. 1 to 5, a current sensor 10 is provided with a main body 20, bus bars 30, a core 40, and magnetic sensors 50. The main body 20 is made of resin, and integrated with the bus bars 30 and the core 40 by insert molding. The current flowing in the bus bars 30 is measured using the core 40 and the magnetic sensors 50.

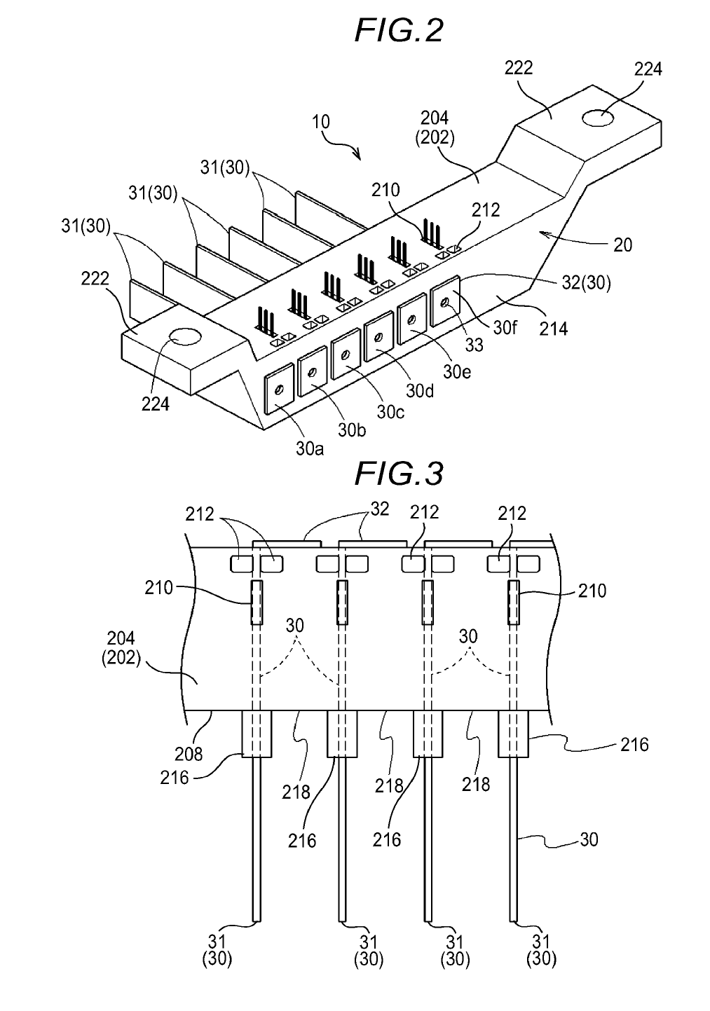

As illustrated in FIGS. 1 and 2, the main body 20 has a central portion 202 where the bus bars 30 are insert-molded, and end portions 222 which are formed at the opposite sides of the central portion 202 in the longitudinal direction. The end portions 222 have a smaller thickness (in an up and down direction in FIG. 1) than the central portion 202, and the end portions 222 are formed in parallel with a front surface 204 of the main body 20 while having a level difference from the surface 204. Mounting holes 224 are formed in the end portions 222, respectively, to mount and fix the current sensor 10 to another member.

Six sensor holding holes 210 in which the magnetic sensors 50 are disposed are formed in the front surface 204 of the main body 20. In addition, six sets (six pairs) of intermediate restriction holes 212 are formed to extend from the front surface 204 to a rear surface 206 of the main body 20 with each bus bar 30 being interposed between one pair of intermediate restriction holes 212 each of which faces the bus bar 30 from one of the inner circumferential surfaces thereof. The six sets of intermediate restriction holes 212 are arranged in parallel and in a straight line in the longitudinal direction of the main body 20. The intermediate restriction holes 212 are an example of hole portions. As necessary, the bus bars 30 may be held at predetermined positions in the main body 20 by disposing protruding members or the like at the positions of the intermediate restriction holes 212 across the bus bar 30 interposed between each pair of intermediate restriction holes 212 when performing the insert molding using a resin.

The bus bars 30 have a rectangular plate shape, and are made of a metal with high conductivity, such as copper or a copper alloy. The current sensor 10 has six bus bars 30 (30a to 30f). One end portion 31 of each of the bus bars 30a to 30f is connected to one of U-phase, V-phase, and W-phase terminals of two three-phase alternating current motors (not illustrated), and the other end portion 32 is connected to an inverter (not illustrated). Therefore, a conducting current flows in the bus bars 30 toward the two three-phase alternating current motors.

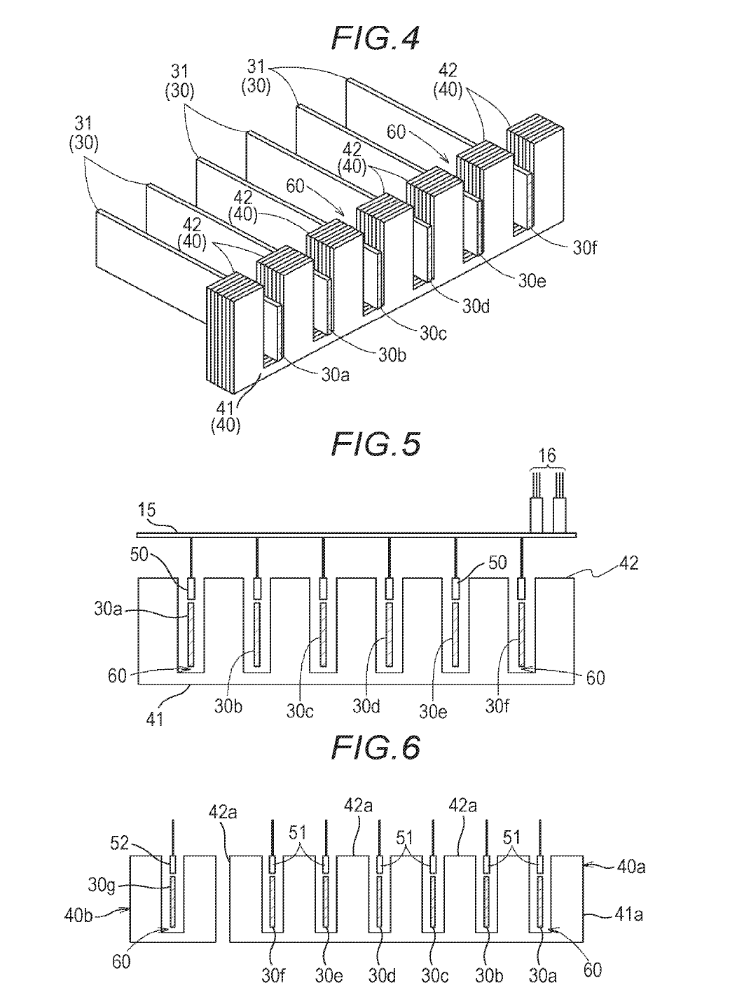

The sensor main body of the current sensor 10 includes the core 40 and the magnetic sensors 50. The core 40 is configured by stacking a plurality of magnetic bodies such as electromagnetic steel sheets. As illustrated in FIGS. 4 and 5, the core 40 has a base portion 41 which is provided in the longitudinal direction of the main body 20, and seven arm portions 42 which extend in a vertical direction from the base portion 41 and are spaced apart from each other. The seven arm portions 42 of the core 40 are arranged so as to hold each of the bus bars 30a to 30f therebetween. That is, the bus bars 30 are respectively inserted into gaps 60 formed in the core 40.

Each magnetic sensor 50 is a device that outputs voltage (signal) depending on a magnitude of a magnetic flux (e.g., a Hall device). As illustrated in FIG. 5, each magnetic sensor 50 is inserted into one of the sensor holding holes 210 (see FIG. 1) of the main body 20, and disposed in one of the gaps 60 each formed between the adjacent arm portions 42. A circuit board 15 is fixed to the upper surface of the main body 20 and processes an output from each magnetic sensor 50. The circuit board 15 is connected to the magnetic sensors 50 and supplies power to the magnetic sensors 50. Signal lines 16 extend upward from the circuit board 15 to transmit a sensor output to a controller of the inverter (a circuit board on which a control circuit of the inverter is mounted).

The main body 20 integrally holds the bus bars 30 and the core 40 in a state of being molded with a resin. As the molding resin, polyphenylene sulfide (PPS), polyphthalamide (PPA), or the like is used. Both of the PPS and the PPA have an excellent insulation property and flame resistance. Therefore, the insulation property may be appropriately maintained in the current sensor 10 and the durability of the current sensor 10 may be improved. When comparing the PPS and the PPA, since the PPA has lower specific gravity and higher insulation property and flame resistance, the PPA may be more preferable as the molding resin of the main body 20.

As illustrated in FIG. 3, in the main body 20, an end surface 208 for holding the bus bars 30 protrudes in the extension direction of the bus bars 30. That is, in the main body 20, the end surface 208 at a side where the bus bars 30 extend has protruding portions 216 that protrude in the extension direction of the bus bars 30. A concave portion 218 is formed between every adjacent protruding portions 216. As the concave portion 218 is formed, a creeping distance between adjacent bus bars 30 is increased. Therefore, the adjacent bus bars 30 may be disposed in an insulated state. In addition, since the creeping distance between the adjacent bus bars 30 is increased without changing the space distance between the adjacent bus bars 30, it is possible to compactly configure the current sensor 10.

FIG. 4 is a view illustrating a relative disposition of the bus bars 30 and the core 40 by omitting the main body 20 from the current sensor 10. The arm portions 42 of the core 40 are disposed to surround the bus bars 30 (30a to 30f).

The bus bars 30a to 30c transmit a single UVW three-phase output current, and the bus bars 30d to 30f transmit another UVW three-phase output current. As illustrated in FIGS. 2 and 3, the one end portions 31 of the bus bars 30 extend from the main body 20, and the other end portions 32 thereof are bent at a right angle at a position corresponding to an end surface 214 of the main body 20. Hole portions 33 are formed in the other end portions 32 to fix power cables of the motors, respectively.

As described above, the current sensor 10 is used by being connected between two three-phase alternating current motors and the inverter. When power is applied to the three-phase alternating current motors, a current flows in the bus bars 30. When the current flows, the magnetic flux is generated around the bus bars 30. The magnitude of the generated magnetic flux is proportional to the magnitude of the flowing current. The generated magnetic flux is collected in the core 40 having low magnetic resistance, and passes through the interior of the core 40. Because the core 40 has the arm portions 42, the magnetic flux passes through air in each gap 60 at tip sides of facing arm portions 42. Because the magnetic sensor 50 is disposed in each gap 60, the magnitude of the magnetic flux in the gap 60 is detected by the magnetic sensor 50, and the magnitude of the current flowing through each bus bar 30 is obtained based on the magnitude of the magnetic flux.

### Another Exemplary Embodiment

(1) In the current sensor 10, seven or more bus bars 30 and a core 40 having eight or more arm portions 42 may be insert-molded in the main body 20. In the case in which the current sensor 10 has, for example, seven bus bars 30, six bus bars may be used for three-phase alternating current motors, and one bus bar may be used for another function. In addition, since the motors perform three-phase output, whenever a motor is added, three bus bars 30 and three arm portions 42 of the core 40 are increased.

(2) Although an example in which the single core 40 is insert-molded in the main body 20 has been illustrated in the first exemplary embodiment, a core 40b may be inserted into the main body 20 to detect a current flowing in a single bus bar 30g, together with an integrated core 40b (see FIG. 6). The core 40a has a base portion 41a and seven arm portions 42a, and bus bars 30a to 30f and magnetic sensors 51 are disposed in gaps 60 each formed between adjacent arm portions 42a. Meanwhile, in the core 40b, the bus bar 30g and a magnetic sensor 52 are disposed in a single gap 60. Therefore, the current sensor 10 may detect a current, which is generated in the bus bar 30g by a device other than the motors, using the core 40b provided separately from the core 40a.

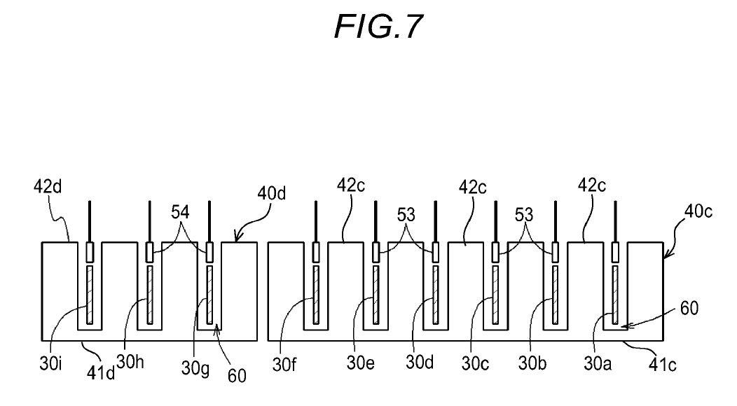

(3) In the case in which three motors are connected to the current sensor 10, for example, the core 40 inserted into the main body 20 may be disposed by being divided into an integrated core 40c for six phases and an integrated core 40d for three phases (see FIG. 7). The core 40c has a base portion 41c and seven arm portions 42c, and bus bars 30a to 30f and magnetic sensors 53 are disposed in gaps 60 each formed between adjacent arm portions 42c. Meanwhile, the core 40d has a base portion 41d and four arm portions 42d, and bus bars 30g to 30i and magnetic sensors 54 are disposed in gaps 60 each formed between adjacent arm portions 42d.

The current sensor disclosed here may be widely used for a current sensor for measuring a current flowing in a bus bar.

A feature of a current sensor according to an aspect of this disclosure resides in that the current sensor includes: six or more bus bars; a core made of a magnetic material and having a base portion and seven or more arm portions which extend in a vertical direction from the base portion and are spaced apart from each other, and in which each of the bus bars is inserted into a gap formed between adjacent arm portions; and a main body configured to integrally hold the bus bars and the core in a state in which the bus bars and the core are insert-molded using polyphenylene sulfide (PPS) or polyphthalamide (PPA).

According to this configuration, the current sensor is configured by insert-molding six or more bus bars and an integrated core having seven or more arm portions using a resin. The integrated core may serve as a framework in the main body. That is, even if the resin is contracted in the main body, the influence of the contraction of the resin is reduced in the inside of the core by a holding function of the integrated core as a framework. As a result, it is possible to prevent positional deviation of the end portions of the bus bars which are disposed in the core. In addition, in the current sensor, since the integrated core is assembled by being inserted into the main body, it is possible to simply assemble the core to the current sensor. In addition, because the integrated core is used such that a dimension in the longitudinal direction of the main body may be reduced, the current sensor may be compactly configured.

Further, in the current sensor having the present configuration, the main body is resin-molded using polyphenylene sulfide (PPS) or polyphthalamide (PPA). Both of the PPS and the PPA have an excellent insulation property and flame resistance. Therefore, insulation property can be appropriately maintained in the current sensor and durability of the current sensor can be improved.

Another feature of the current sensor resides in that the main body has a protruding portion that is formed as an end portion of the main body, which holds the bus bars, protrudes in an extension direction of the bus bars.

In the current sensor, the bus bars are disposed in an insulated state from other adjacent bus bars. In order to establish this insulated state, it is required to ensure a predetermined creeping distance between the adjacent bus bars. According to the present configuration, the main body has a protruding portion that is formed as the end portion of the main body, which holds the bus bars, protrudes in the extension direction of the bus bars. Therefore, a concave portion is formed in an outer surface of the main body between adjacent bus bars. With the concave portion, a creeping distance between adjacent bus bars is increased. Therefore, adjacent bus bars may be disposed in an insulated state. In addition, since the creeping distance between adjacent bus bars is increased without changing a space distance between the adjacent bus bars, it is possible to compactly configure the current sensor.

Still another feature of the current sensor resides in that the main body has a pair of hole portions that are respectively formed at opposite sides of each of the bus bars interposed therebetween.

When the bus bars are integrated with the main body by resin molding, the opposite end portions of the bus bars are hold in the mold. However, even if the opposite end portions of the bus bars are held in the mold, positional accuracy of the end portions of the bus bars may not be sufficient in the main body after the molding in some cases. Therefore, in the present configuration, the main body has a pair of hole portions formed at the opposite sides of each bus bar interposed therebetween. Therefore, the main body may be resin-molded, for example, in a state in which protruding members or the like are disposed at positions of the hole portions and each the bus bars is fitted between the protruding members. As a result, since the positions of the bus bars become stable in the main body, it is possible to improve positional accuracy of the end portions of the bus bars in the current sensor.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A current sensor comprising:
six or more bus bars;
a core made of a magnetic material and having a base portion and seven or more arm portions which extend in a vertical direction from the base portion and are spaced apart from each other, and in which each of the bus bars is inserted into a gap formed between adjacent arm portions; and
a main body configured to integrally hold the bus bars and the core in a state in which the bus bars and the core are insert-molded using polyphenylene sulfide (PPS) or polyphthalamide (PPA).

2. The current sensor according to claim 1, wherein the main body has a protruding portion that is formed as an end portion of the main body, which holds the bus bars, protrudes in an extension direction of the bus bars.

3. The current sensor according to claim 1, wherein the main body has a pair of hole portions that are respectively formed at opposite sides of each of the bus bars interposed therebetween.
